(19) United States
(12) Patent Application Publication
(10) Pub. No.: US 2008/0296713 A1
(43) Pub. Date: Dec. 4, 2008

(54) Image Sensor with Color Filters and Method of Manufacturing the Same

(76) Inventors: Byoung Su Lee, Jeollanam-do (KR); Jun Ho Won, Seoul (KR)

Correspondence Address: IPLA P.A., 3580 WILSHIRE BLVD., 17TH FLOOR, LOS ANGELES, CA, 90010, US

(21) Appl. No.: 12/097,477

(22) PCT Filed: Dec. 7, 2006
(86) PCT No.: PCT/KR06/05265

§ 371 Date: Jun. 13, 2008

(30) Foreign Application Priority Data
Jan. 3, 2006 (KR) 10-2006-0000452
Dec. 7, 2006 (KR) PCT/KR2006/005265

(51) Int. Cl. H01L 31/0232; H01L 31/18

(52) U.S. Cl. 257/432; 438/70; 257/E31.127

(57) ABSTRACT

An image sensor with color filters capable of minimizing a distance through which incident light reaches photodiodes and flattening the color filters by minimizing step heights among color filters, and a method of manufacturing the same are provided. In the image sensor with the color filters, a metal is doped into an interlayer insulating SiO₂ layer opened through a photosensitive film, and the color filters of red, green, and blue are formed in the interlayer insulating SiO₂ layer through a heat treatment. In this case, a color filter array can be flattened by removing step heights among color filters generated in an conventional method in which the interlayer insulating SiO₂ layer is sequentially coated with the color filters of red, green, and blue so as to form a color filter array. In addition, the distance through which the incident light reaches the photodiodes can be reduced by forming the color filters in the interlayer insulating SiO₂ layer, thereby improving the sensitivity of the image sensor.

### TECHNICAL FIELD

The present invention relates to an image sensor, and more particularly, to an image sensor with color filters of red, green, and blue obtained by injecting metals into a SiO₂ layer that is used as a flattened layer and treating the SiO₂ layer with heat instead of color filters having polymer components and a method of manufacturing the same.

### BACKGROUND ART

An image sensor is an element for outputting an image signal of a subject using color filters. The image sensor is generally manufactured by using color filters which contains polymer components.

FIG. 1 is a cross sectional view illustrating an image sensor with conventional color filters. In the image sensor, photodiodes 120 are formed on a silicon substrate 110, and a color filter array of green 150, red 160, and blue 170 and microlenses 180 are formed on an interlayer insulating film 130 and a plurality of metal wires 140.

In the conventional color filters, step heights among color filters are caused by sequentially forming the color filters by using repeated coating and developing processes. Accordingly, an additional flattened layer is formed on the color filters before upper microlenses are formed.

However, uniformity of light with a wavelength range which is transmitted through the microlenses deteriorates.

In addition, the intensity and the concentration degree of incident light are reduced by increasing the distance between the microlenses and the photodiodes by coating the interlayer insulating SiO₂ film with the color filter array after the interlayer insulating SiO₂ film is formed.

### DISCLOSURE OF INVENTION

### Technical Problem

The present invention provides an image sensor capable of improving a sensitivity of the image sensor by reducing a distance through which incident light transmitted through the color filters reaches photodiodes, since shapes of microlenses are further uniformized by forming a color filter array as a flattened layer without step heights among color filters by injecting metals into an interlayer insulating SiO₂ layer that is used as the flattened layer.

### Technical Solution

According to an aspect of the present invention, there is provided an image sensor with SiO₂ color filters, the image sensor comprising: a plurality of photodiodes which are formed at a predetermined depth from a surface of a silicon substrate; an interlayer insulating SiO₂ layer which is formed on the silicon substrate and flattened; a plurality of metal wires which are formed in the interlayer insulating SiO₂ layer as pre-determined patterns; a plurality of color filters which are formed by injecting a pre-determined metal from the surface of the interlayer insulating SiO₂ layer to a pre-determined depth and treating the interlayer insulating SiO₂ layer with heat to display green, red, and blue; and a plurality of micro-lenses which are formed on the color filters.

According to another aspect of the present invention, there is provided a method of manufacturing an image sensor, the method comprising steps of: (a) forming a plurality of photodiodes at a predetermined depth from a surface of a silicon substrate; (b) forming a flattened interlayer insulating SiO₂ layer on the silicon substrate; (c) forming a plurality of metal wires in the interlayer insulating SiO₂ layer as pre-determined patterns; (d) forming color filters of green, red, and blue from the surface of the interlayer insulating SiO₂ layer to a predetermined depth by injecting metals by using a predetermined process; and (e) forming microlenses on the color filters.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross sectional view illustrating an image sensor with an conventional color filter;

FIGS. 2 and 3 are cross sectional views illustrating image sensors with color filters according to embodiments of the present invention;

FIG. 4 is a flowchart illustrating a method of manufacturing an image sensor with color filters according to an embodiment of the present invention; and

FIGS. 5 and 6 are cross sectional views for illustrating methods of manufacturing an image sensor with color filters according to embodiments of the present invention.

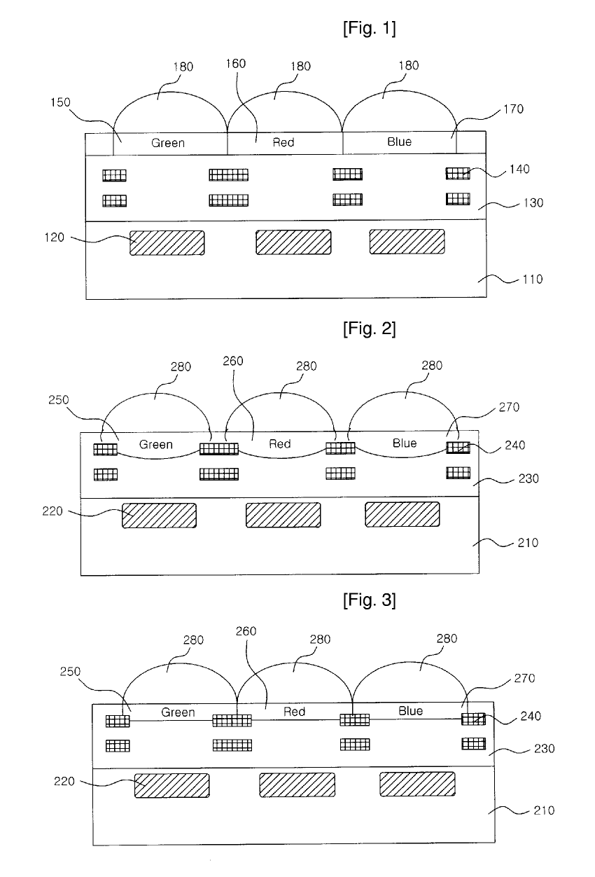

### BEST MODE FOR CARRYING OUT THE INVENTION

Hereinafter, the present will be described in detail with reference to accompanying drawings.

FIG. 2 is a cross sectional view illustrating an image sensor with color filters according to an embodiment of the present invention. FIG. 3 is a cross sectional view illustrating an image sensor with color filters according to another embodiment of the present invention.

Referring to FIGS. 2 and 3, the image sensor with color filters according to the embodiment of the present invention includes a silicon substrate 210, a plurality of photodiodes 220 that is formed in the silicon substrate 210, an interlayer insulating SiO₂ layer 230 that is formed on the silicon substrate 210, metal wires 240 that is formed in the interlayer insulating SiO₂ layer, a plurality of color filters 250, 260, and 270 of green, red, and blue that are formed in the interlayer insulating SiO₂ layer from the surface of the interlayer insulating SiO₂ layer to a predetermined depth, and a plurality of microlenses 280 that are formed on the color filters.

Specifically, the plurality of color filters 250, 260, and 270 are respectively formed over the photodiodes corresponding to green 250, red 260, and blue 270 of a color filter array. The color filters 250, 260, and 270 are formed by injecting metals such as iron, copper, and cobalt into the interlayer insulating SiO₂ layer by using a pre-determine process and treating the SiO₂ layer with heat.

In FIG. 2, the color filters of the image sensor according to an embodiment of the present invention are formed by masking using a photosensitive film. In FIG. 3, the color filters are formed by using a spin on glass (SOG) layer that contains metals.

Since the color filters are formed in the flattened interlayer insulating SiO₂ layer, regardless of the methods of forming the color filters, sensitivity of the image sensor with the color filters according to an embodiment of the present invention is improved.

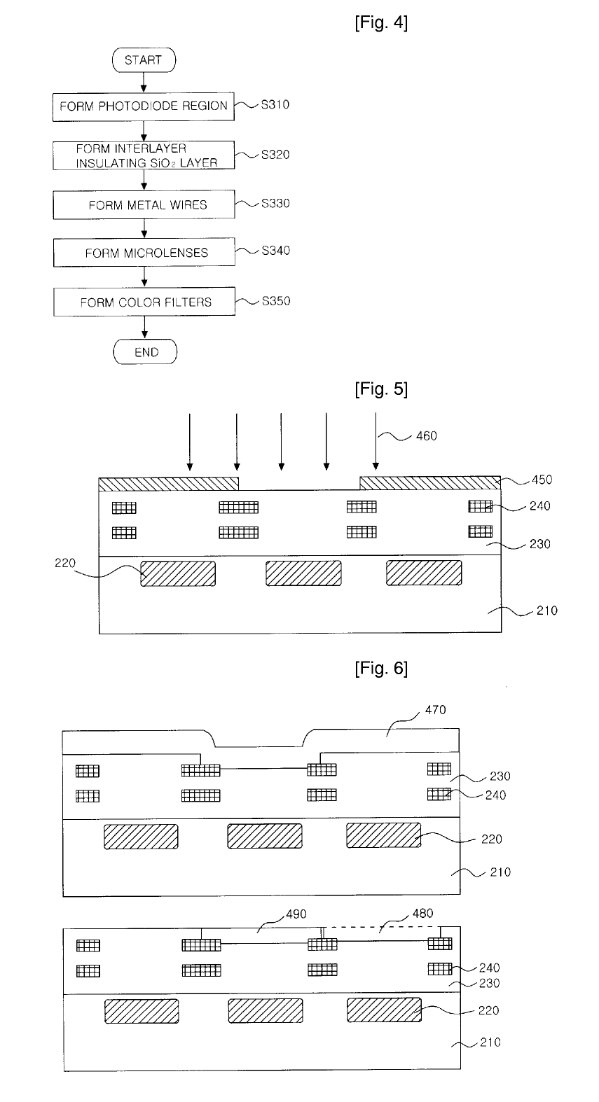

FIG. 4 is a flowchart illustrating a method of manufacturing an image sensor with color filters according to an embodiment of the present invention. The method of manufacturing the image sensor includes steps of forming photodiodes (S310), forming an interlayer insulating SiO₂ layer (S320), forming metal wires (S330), forming color filters (S340), and forming microlenses (S350).

Referring to FIG. 2, the steps of manufacturing image sensors with color filters according to an embodiment of the present invention are described based on the components of FIG. 4.

In the step of forming the photodiodes (S310), the plurality of photodiodes 220 are formed at a predetermined depth from the surface of the silicon substrate 210. In the step of forming the interlayer insulating SiO₂ layer, the SiO₂ layer 230 for interlayer insulation is formed on the silicon substrate 210. In the step of forming metal wires (S330), the plurality of metal wires 240 are formed in the interlayer insulating SiO₂ layer 230 as predetermined patterns.

Since the steps (S310 to S330) from the step of forming the photodiodes to the step of forming the metal wires are the same as those of a method of manufacturing an conventional image sensor, detailed description thereof will be omitted.

In the step of forming the color filters (S340), the color filters 250, 260, and 270 of green, red, and blue are formed by injecting metals from the surface of the interlayer insulating SiO₂ layer 230 to a predetermined depth by using a predetermined process.

The metals corresponding to the color filters may be one or more among metals such as iron (Fe), copper (Cu), cobalt (Co), mangan (Mn), and antimony (Sb).

Processes of injecting metals into the interlayer insulating SiO₂ layer include a process of injecting metal impurities into the interlayer insulating SiO₂ layer and treating the SiO₂ layer with heat, a process of injecting metals through a SOG layer that contains metal impurities, and a process of injecting metals into the SiO₂ layer by depositing the metals on the interlayer insulating SiO₂ layer and diffusing the metals into the interlayer insulating SiO₂ layer and treating the SiO₂ layer with heat.

In the step of forming the microlenses (S350), the microlenses are formed on the color filters.

FIG. 5 illustrates a method of manufacturing an image sensor with color filters according to an embodiment of the present invention, and more particularly, a method of forming color filters through making using a photosensitive film so as to manufacture the image sensor of FIG. 2.

In order to form color filters 250, 260, and 270 through masking using a photosensitive film, injection of corresponding metal ions are performed on a masking film 450 so that the corresponding metal ions may be injected into the interlayer insulating SiO₂ layer 230 through an injection path 460 at a suitable energy and dose. Then, the masking film 450 is removed, and the corresponding metal ions are diffused into the interlayer insulating SiO₂ layer 230 through a suitable heat treatment.

FIG. 6 illustrates a method of manufacturing an image sensor with color filters according to an embodiment of the present invention, and more particularly, a method of forming color filters using a SOG film that contains metals so as to manufacture the image sensor of FIG. 3.

A region of the interlayer insulating SiO₂ layer 230 in which a color filter 250, 260, or 270 is to be formed are etched to a suitable depth so as to form a well 480. The well 480 is filled with a SiO₂ layer 470 such as the SOG, which contains metals in order to form the color filters and has good fluidity. A plurality of color filters to be arrayed are formed by removing the SiO₂ layer 470 by using an etch-back or chemical mechanical polishing (CMP) process except the region 490 in which the color filter 250, 260, or 270 is to be formed.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

An image sensor with color filters according to embodiment of the present invention and an image sensor manufactured by a method of manufacturing the same have a good flatness of color filters and a high condensing rate of incident light as compared with an existing color filter.

1. An image sensor with color filters, the image sensor comprising:
a plurality of photodiodes which are formed at a predetermined depth from a surface of a silicon substrate;
an interlayer insulating SiO₂ layer which is formed on the silicon substrate and flattened;
a plurality of metal wires which are formed in the interlayer insulating SiO₂ layer as predetermined patterns;
a plurality of color filters which are formed by injecting a predetermined metal from the surface of the interlayer insulating SiO₂ layer to a predetermined depth and treating the interlayer insulating SiO₂ layer with heat to display green, red, and blue; and
a plurality of micro-lenses which are formed on the color filters.

2. The image sensor according to claim 1, wherein the metal is one of iron (Fe), copper (Cu), cobalt (Co), mangan (Mn), and antimony (Sb).

3. A method of manufacturing an image sensor comprising steps of:
(a) forming a plurality of photodiodes at a predetermined depth from a surface of a silicon substrate;
(b) forming a flattened interlayer insulating SiO₂ layer on the silicon substrate;
(c) forming a plurality of metal wires in the interlayer insulating SiO₂ layer as predetermined patterns;
(d) forming color filters of green, red, and blue from the surface of the interlayer insulating SiO₂ layer to a predetermined depth by injecting metals by using a pre-determined process; and
(e) forming microlenses on the color filters.

4. The method according to claim 3, wherein the metals are one or more of iron (Fe), copper (Cu), cobalt (Co), mangan (Mn), and antimony (Sb).

5. The method according to claim 3, wherein in the step (d), the metal is injected into the interlayer insulating SiO₂ layer by a process of injecting metal impurities into the SiO₂ layer and treating the SiO₂ layer with heat.

6. The method according to claim 5, wherein the process of injecting the metal impurities into the SiO₂ layer and treating the SiO₂ layer with heat comprises steps of:
(d11) forming a masking film on the surface of the interlayer insulating SiO₂ layer;
(d12) injecting ionized metals into the interlayer insulating SiO₂ layer at a suitable energy and dose through the masking film; and
(d13) diffusing the corresponding metal ions into the interlayer insulating SiO₂ layer through a suitable heat treatment after the masking film is removed.

7. The method according to claim 3, wherein in the step (d), the metals are injected into the interlayer insulating SiO₂ layer by a process of injecting the metal impurities into the SiO₂ layer through a SOG (spin on glasses) film that contains the metal impurities.

8. The method according to claim 7, wherein the process of injecting the metal impurities into the SiO₂ layer through the SOG film that contains the metal impurities comprises steps of:
(d21) forming a well by etching a region of the interlayer insulating SiO₂ layer in which the color filter is to be formed;
(d22) filling the well with the SOG film which contains the metal impurities; and
(d23) removing the SOG film except the region in which the color filter is to be formed.

9. The method according to claim 8, wherein in the step (d23), the SOG film is removed by an etch-back or chemical mechanical polishing (CMP) process.

10. The method according to claim 3, wherein in the step (d), the metal is injected into the interlayer insulating SiO₂ layer by a process of depositing the metal on the interlayer insulating SiO₂ layer, injecting into the interlayer insulating SiO₂ layer through diffusion, and treating the interlayer insulating SiO₂ layer with heat.
